(19) United States
(12) Patent Application Publication
(10) Pub. No.: US 2008/0271783 A1
(43) Pub. Date: Nov. 6, 2008

(54) PHOTOVOLTAIC DEVICE AND MANUFACTURING METHOD THEREOF

(75) Inventors: Tsutomu Murakami, Shiga (JP); Shoji Nishida, Kanagawa (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 12/169,597

(22) Filed: Jul. 8, 2008

Related U.S. Application Data
(62) Division of application No. 10/971,130, filed on Oct. 25, 2004.

(30) Foreign Application Priority Data
Nov. 5, 2003 (JP) 2003-375546

(51) Int. Cl. H01L 31/00

(52) U.S. Cl. 136/258

(57) ABSTRACT

There is provided a photovoltaic device in which at least one pin-junction is formed in a thin film semiconductor deposited on a substrate, the substrate including: a base including polycrystalline silicon; and a polycrystalline silicon layer formed on the base by liquid phase growth, in which at least a part of a surface of the polycrystalline silicon layer has unevenness composed of facet surfaces. The photovoltaic device prevents a reduction in photoelectric conversion efficiency due to the absence of preferable unevenness, an increase in cost due to the use of an expensive material, and a reduction in throughput in the photovoltaic device, and has a preferable characteristic and high productivity.

### BACKGROUND OF THE INVENTION

1. Field of the Invention

The present invention relates to an improved photovoltaic device, more particularly to a structure for effectively utilizing incident light on a photovoltaic device and a method of manufacturing a photovoltaic device having the structure.

2. Related Background Art

A solar cell which is an application example of a photovoltaic device using a semiconductor has received attention as a device for solving energy problems and environmental problems. In recent years, practical use of the solar cell has been promoted to such an extent that the solar cell mounted on a roof of a general house may cover power consumption of the house. Such a solar cell is mainly made of a semiconductor such as silicon or CdS. In particular, because of pollution free and a large amount of deposits, silicon is the most widespread material for the solar cell under the current circumstances.

The silicon used for manufacturing the solar cell is broadly divided into single crystalline silicon and non-single crystalline silicon. The non-single crystalline silicon is divided into polycrystalline silicon, amorphous silicon, micro-crystalline silicon, and the like. Crystalline silicon is now widespread. In the future, because slimming is possible and the amount of material to be used is small, a thin film semiconductor of the amorphous silicon or crystalline silicon (also referred to as thin film polycrystalline silicon or thin film micro-crystalline silicon) having a very small grain size, such as the micro-crystalline silicon is promising.

Under the current circumstances, conversion efficiency of the solar cell for converting optical energy into electrical energy is low. Therefore, researches for minimizing various electrical losses and shadow losses and effectively utilizing incident light have been concentratedly conducted in view of necessity of minimizing a conversion loss.

A structure of a solar cell using the amorphous silicon, the micro-crystalline silicon, or the like as a photovoltaic semiconductor is as follows. According to a first structure, a light receiving surface electrode, a semiconductor layer, and a rear electrode are stacked in order on a translucent substrate made of glass or the like. According to a second structure, the rear electrode, the semiconductor layer, and the light receiving surface electrode are stacked in order on a substrate. A material such as translucent glass or non-translucent stainless steal is used for the substrate in the second structure. The semiconductor layer has a so-called pin-junction in which a p-layer, an i-layer, and an n-layer which are made of the amorphous silicon or the micro-crystalline silicon are stacked.

According to a conventional technique for improving the conversion efficiency of the solar cell, unevenness is formed on the light incident side surface of the semiconductor layer and the rear electrode. Therefore, light is scattered on the light incident side and light which reaches a rear surface without absorption after light incidence is scattered and reflected on the rear electrode, thereby lengthening an optical path length.

According to, for example, Japanese Patent application Laid-Open No. H09-307130 or Japanese Patent application Laid-Open No. H10-117006 as a first conventional example related to such a technique, minute unevenness having an uneven difference of 0.05 μm to 3 μm is provided on the surface of a polycrystalline silicon thin film. When light is obliquely incident on a solar cell and multi-reflected between the rear surface and front surface thereof, an effective optical path length increases. Therefore, although the solar cell is a thin film, the large amount of light absorption is obtained. According to a method of providing the uneven difference, an n⁺-type polycrystalline silicon layer is deposited as a base electroconductive layer on a substrate at a temperature equal to or higher than 500° C. by a thermal CVD method. Unevenness is formed by adjusting a deposition condition. With respect to a polycrystalline photoelectric conversion layer deposited after that, crystal grains are formed in the <110> direction relative to the thickness direction and unevenness is formed on the surface corresponding to the {100} plane.

FIG. 9 is a schematic structural view showing a conventional photovoltaic device. In FIG. 9, the photovoltaic device includes a glass substrate 901, a base electroconductive layer 902, a metallic layer 903, an n-layer 904, an i-layer 905, a p-layer 906, and a transparent electrode 907.

With respect to a second conventional example, a method of directly providing unevenness on a metallic electrode and a method of providing unevenness on an oxide semiconductor layer have been devised as methods of providing unevenness on the rear electrode. Such a devise is described in, for example, Japanese Patent application Laid-Open No. H10-150209. According to the devise, a lower electroconductive layer surface is formed in an uneven shape and surface roughness Ra in a length of several tens of μm is set to 0.1 μm to 1 μm. Therefore, a optical confinement effect is shown, thereby significantly improving a short circuit photo-current of a photoelectric conversion element.

However, the structure related to the first conventional example requires the base electroconductive layer. In addition, because a photovoltaic semiconductor layer requires a crystalline structure to obtain orientation, the photovoltaic semiconductor layer is limited to a polycrystalline silicon layer. With respect to a manufacturing limitation, the base electroconductive layer and the polycrystalline silicon layer are formed at a temperature equal to or higher than 500° C. Therefore, it is necessary to use an expensive substrate made of, for example, glass resistant to such a high temperature. With respect to a technical problem in the case where the glass substrate is used, because of a structure in which energy is collected from the base electroconductive layer and the rear electrode, the base electroconductive layer and the rear electrode should be thickened to reduce a sheet resistance or an increase in current should be prevented by scribing every 10 mm in width to make series connection.

In the second conventional example, when a light reflection enhancement film of the base electroconductive layer made of zinc oxide or the like is formed in a desirable uneven shape, it is required to set a film thickness of the light reflection enhancement film to several μm. Therefore, an increase in material cost and a reduction in throughput occur. The uneven shape is technically achieved by controlling a size of a crystal grain and crystalline orientation, so that there is a limitation on an uneven difference of unevenness and a pitch thereof. Accordingly, it is hard to obtain a large uneven difference and a large pitch. The base electroconductive layer having the small uneven shape is sufficient to scatter reflection light. However, the semiconductor thin film is not accurately formed on the base electroconductive layer along the base shape thereof, so that the unevenness on the surface of the semiconductor thin film tends to become dull. Thus, with respect to the light incident side, it is not possible to sufficiently effectively use light with the unevenness.

### SUMMARY OF THE INVENTION

An object of the present invention is to provide a structure of a photovoltaic device that prevents a reduction in photoelectric conversion efficiency due to the absence of preferable unevenness, an increase in cost due to the use of an expensive material, and a reduction in throughput in the conventional photovoltaic device, includes a power generating layer made from a thin film, which is formed in advance on a low cost substrate having preferable unevenness, and has a preferable characteristic and high productivity, and a method of manufacturing the photovoltaic device having the structure.

To attain the above objects, according to one aspect of the present invention, there is provided a photovoltaic device in which at least one pin-junction is formed in a thin film semiconductor deposited on a substrate,

the substrate including:

a base including polycrystalline silicon; and

a polycrystalline silicon layer formed on the base by liquid phase growth,

in which at least a part of a surface of the polycrystalline silicon layer has unevenness composed of facet surfaces.

In further aspect of the photovoltaic device, the base is a slice of a polycrystalline silicon ingot produced by melting and solidifying silicon.

In further aspect of the photovoltaic device, at least a part of the unevenness on the surface of the polycrystalline silicon layer has a groove shape, a triangular pyramid shape, or a pentahedron shape.

In further aspect of the photovoltaic device, an average of tilt angles of the facet surfaces composing the unevenness is equal to or larger than 30° relative to the base.

In further aspect of the photovoltaic device, an average of uneven differences of the unevenness is 0.05 μm to 10 μm.

In further aspect of the photovoltaic device, a metallic electrode layer is further formed on the surface of the polycrystalline silicon layer.

In further aspect of the photovoltaic device, an oxide semiconductor layer is further formed on a surface of the metallic electrode layer.

In further aspect of the photovoltaic device, the polycrystalline silicon layer includes high purity silicon and a layer having a conductivity type different from a conductivity type of the polycrystalline silicon layer including high purity silicon is formed on the polycrystalline silicon layer including the high purity silicon to form a pn-junction for serving as a bottom cell of the photovoltaic device.

In further aspect of the photovoltaic device, an oxide semiconductor layer is further formed on the surface of the polycrystalline silicon layer including the high purity silicon.

In further aspect of the photovoltaic device, the conductivity type of the polycrystalline silicon layer including the high purity silicon is equal to a conductivity type of the polycrystalline silicon of the base and resistivity of the polycrystalline silicon layer including the high purity silicon is 0.1 Ω·cm to 10 Ω·cm.

According to another aspect of the present invention, there is provided a method of manufacturing a photovoltaic device in which at least one pin-junction is formed in a thin film semiconductor deposited on a substrate, including a substrate forming step,

the substrate forming step including the steps of:

forming a base of a polycrystalline silicon ingot by melting and solidifying silicon; and

forming a polycrystalline silicon layer on the base by a liquid phase growth method, at least a part of a surface of the polycrystalline silicon layer having an uneven shape composed of facet surfaces.

In further aspect of the method of manufacturing a photovoltaic device, a method of melting and solidifying the silicon includes unidirectional solidification.

In further aspect of the method of manufacturing a photovoltaic device, at least a part of the unevenness on the surface of the polycrystalline silicon layer has a groove shape, a triangular pyramid shape, or a pentahedron shape.

### BRIEF DESCRIPTION OF THE DRAWINGS

FIG. 1 is a schematic view showing a photovoltaic device of a single cell according to Embodiment 1 of the present invention;

FIG. 2 is a schematic view showing a photovoltaic device of another single cell according to Embodiment 1 of the present invention;

FIG. 3 is a schematic view showing a photovoltaic device of a double cell according to Embodiment 2 of the present invention;

FIG. 4 is a schematic view showing a photovoltaic device of another double cell according to Embodiment 2 of the present invention;

FIG. 5 is a schematic view showing a photovoltaic device of another double cell according to Embodiment 2 of the present invention;

FIG. 6 is a schematic view showing an optical path of an incident light beam in the photovoltaic device according to Embodiment 1 of the present invention;

FIG. 7 is a schematic view showing the photovoltaic device of the double cell in which a grid electrode and a rear electrode are formed, according to Embodiment 2 of the present invention;

FIG. 8 is a schematic view showing a photovoltaic device in which another grid electrode is formed, according to Embodiment 2 of the present invention;

FIG. 9 is a schematic view showing a conventional photovoltaic device;

FIG. 10 is a schematic view showing a first preferred shape of unevenness formed on a polycrystalline silicon surface in the photovoltaic device of the present invention;

FIG. 11A is a schematic view showing a second preferred shape of unevenness formed on the polycrystalline silicon surface in the photovoltaic device of the present invention.

FIG. 11B is a schematic view showing a third preferred shape of unevenness formed on the polycrystalline silicon surface in the photovoltaic device of the present invention;

FIG. 12 is a graph showing a measurement example of the first preferred shape of the unevenness formed on the polycrystalline silicon surface in the photovoltaic device of the present invention;

FIG. 13 is a graph showing a measurement example of the second preferred shape of the unevenness formed on the polycrystalline silicon surface in the photovoltaic device of the present invention;

FIG. 14 is a graph showing quantum efficiency of a solar cell having the unevenness with the first preferred shape on the polycrystalline silicon surface;

FIG. 15 is a graph showing quantum efficiency of a solar cell having the unevenness with the second preferred shape on the polycrystalline silicon surface;

FIG. 16 is a graph showing a relationship between a tilt angle of the unevenness formed on the polycrystalline silicon surface and a current value of a solar cell;

FIG. 17 is a schematic view showing a silicon manufacturing apparatus; and

FIG. 18 is a schematic view showing a liquid phase growth apparatus.

### DESCRIPTION OF THE PREFERRED EMBODIMENTS

Next, the present invention will be described in detail with reference to the accompanying drawings.

According to the present invention, when liquid phase growth is performed using polycrystalline silicon base, minute unevenness is formed on a surface obtained as a consequence of the liquid phase growth, so that the resultant polycrystalline silicon can be used as a preferable texture substrate. Then, a thin film semiconductor is formed on the texture substrate, thereby obtaining a solar cell that realizes the effective use of light. Hereinafter, preferred embodiments of the present invention will be described with reference to the accompanying drawings.

### Embodiment 1

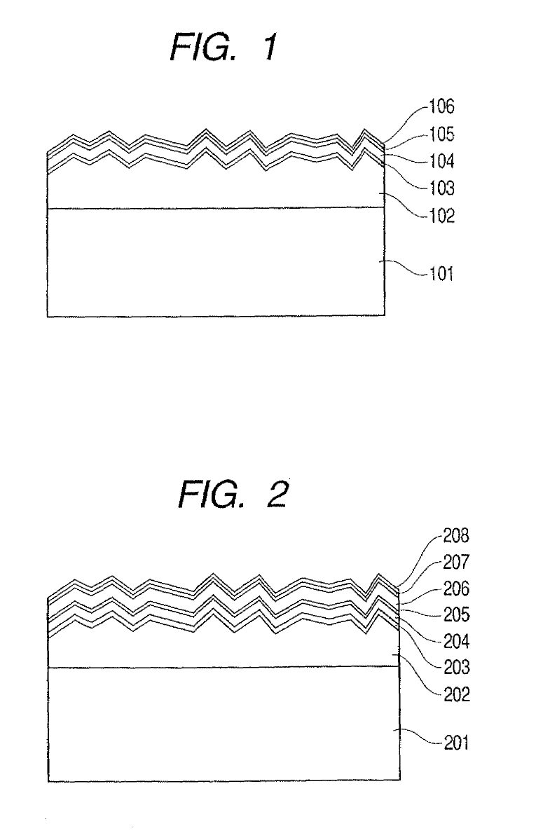

FIGS. 1 and 2 show the first example of the preferred embodiments of the present invention.

FIG. 1 shows a structure in which a polycrystalline silicon layer is formed on a silicon base by liquid phase growth to obtain a substrate and a single cell made of thin film system silicon is formed above the substrate.

In FIG. 1, a photovoltaic device includes a base 101 made of silicon, a polycrystalline silicon layer 102, an n-layer 103, an i-layer 104, a p-layer 105, and a transparent electrode layer 106. In such a structure, the base 101 and polycrystalline silicon layer 102 each have a p⁺ conductivity type. The n-layer 103 made of amorphous silicon (hereinafter referred to as a-Si), the i-layer 104 made of a-Si, amorphous silicon germanium (hereinafter referred to as a-SiGe), or micro-crystalline silicon (hereinafter referred to as μc-Si), and the p-layer 105 made of μc-Si are formed, and the transparent electrode layer 106 made of ITO or the like is finally formed thereon.

FIG. 2 shows a structure in which a metallic electrode layer, an oxide semiconductor layer, and a single cell made of a-Si, a-SiGe, or μc-Si are stacked in order on the substrate having the polycrystalline silicon layer in the structure shown in FIG. 1.

In FIG. 2, a photovoltaic device includes a base 201 made of silicon, a polycrystalline silicon layer 202, a metallic electrode layer 203, an oxide semiconductor layer 204, an n-layer 205, an i-layer 206, a p-layer 207, and a transparent electrode layer 208. In such a structure, the base 201 and polycrystalline silicon layer 202 each have a p⁺ conductivity type. The transparent electrode layer 208 made of ITO or the like is finally formed on the single cell made of a-Si, a-SiGe, or μc-Si.

The following description will be described with reference to FIG. 2.

### (Silicon Base)

In the present invention, silicon material formed from solar-grade polycrystalline silicon ingot or ribbon crystal is preferably used for the base 201. For lower cost photovoltaic devices, low purity silicon is more preferably used for the base 201. A silicon material serving as the low purity silicon which is a lowest cost and abundantly provided is metallurgical grade silicon obtained by directly reducing silica stone. The metallurgical grade silicon is not produced in Japan and imported from Norway, Brazil, China, and the like. Although, the nominal purity of the metallurgical grade silicon is generally 98% to 99.5%, types and concentrations of impurities actually contained therein are changed according to silica stone as a raw material. A main impurity includes heavy metal such as Fe, Cr, or Cu. Each of the impurities produces a deep level in silicon and becomes a recombination center, so that a solar cell characteristic significantly deteriorates. Since the heavy metal is likely to diffuse, when the heavy metal is contained in a material of the base at a high concentration, wide range contamination is likely to cause in a step of growing a high purity silicon layer or a process for manufacturing a solar cell. Since the metallic impurities are aggregated to form minute particles, this becomes a cause of shunting the solar cell.

An impurity serving as a dopant such as boron or phosphorus is also contained in the metallurgical grade silicon at a high concentration. In general, the concentration of the boron is relatively high. When the metallurgical grade silicon is produced as an ingot, it exhibits a p-type (resistivity is about 0.1 Ω·cm) in many cases. In some cases, the metallurgical grade silicon exhibits an n-type according to a use material.

Assume that, because the concentration of the dopant such as boron or phosphorus is high, the resistivity of a silicon material originally used for a semiconductor class or a solar cell class is out of specifications (substantially equal to or smaller than 0.1 Ω·cm as described later). In this case, even when a solar cell is manufactured using such a silicon material, the efficiency of the resultant solar cell is low, so that the solar cell cannot be practically used. The silicon material is available at lower cost as compared with general high purity silicon, with the result that the silicon material can be efficiently utilized as “the low purity silicon” serving as the material of the present invention.

### (Method of Producing Silicon Base)

A known method is preferably used as a method of producing the base 201 made of silicon, particularly when the base 201 is made of low purity silicon. Briefly, an ingot of polycrystalline silicon is obtained by melting and solidifying raw silicon with which a crucible is filled, and sliced at a predetermined thickness by a wire saw to form the base 201. A known apparatus as disclosed in, for example, Japanese Patent Application Laid-Open No. H05-147918 is preferably used as an ingot solidification apparatus preferable to embody the present invention. FIG. 17 is a schematic view showing the apparatus. FIG. 17 shows a state in which the raw silicon is being melted and solidified. In FIG. 17, a heater 1702 and a cooling plate 1701 are located around a crucible 1703. A temperature gradient is produced from a lower portion of the crucible 1703 to an upper portion thereof by the operations of the heater 1702 and the cooling plate 1701. In such a state, melted silicon 1705 is formed in the upper portion of the crucible 1703 and solidified silicon 1704 is formed in the lower portion of the crucible 1703.

According to the above-mentioned method, melted metallic silicon is continuously cooled in a direction. Therefore, the melted metallic silicon is solidified while impurities are continuously moved into a melt, thereby producing high purity silicon.

Such a solidification method is called unidirectional solidification. In this time, the concentration of the heavy metal impurity can be reduced up to a concentration by a segregation effect. In the cases of boron and phosphorus, the concentration of the heavy metal impurity cannot be reduced because the segregation effect is extremely weak, so that the resistivity is too low in many cases. Therefore, even when the formed polycrystalline silicon is used for a solar cell without being processed, the resultant solar cell cannot be practically used.

Thus, the base 201 made of the silicon serves as an electroconductive substrate. The substrate can be generally produced by the above-mentioned method at a lower cost than those in glass, ceramics, stainless steel, and a polyimide film, which are used for a solar cell substrate of a thin film system.

The ingot formed by the above-mentioned method is sliced at a thickness of 200 μm to 350 μm by an internal blade type cutter or a wire saw to form a plate serving as the base. When the base is used for the solar cell, it is suitable to use the wire saw having high productivity. Since sawing remainders of the wire saw are left on the surface of the base obtained by slicing and contamination is also deposited thereon, etching is performed after washing. The surface of a substrate for the solar cell is damaged by an alkali etching solution to obtain a texture structure in many cases. According to the present invention, the silicon layer is formed on the base by liquid phase growth to provide a texture. Therefore, after washing with a solvent, the surface of the base may be planer-etched for leveling by, for example, a mixture of nitric acid, acetic acid, and hydrofluoric acid for several minutes. A surface which is not level causes abnormal growth.

### (Liquid Phase Growth)

In the case of the liquid phase growth of the polycrystalline silicon layer 202, low melting point metal such as tin, indium, gallium, aluminum, or copper is melted and silicon is melted into the low melting point metal to obtain a melt. Among tin, indium, gallium, aluminum, and copper, indium is suitable to grow high quality silicon because the melting point of indium is moderately low, indium is easy to treat, and indium is hard to solubilize into silicon. Copper is suitable to rapidly grow silicon because copper has high solubility to silicon.

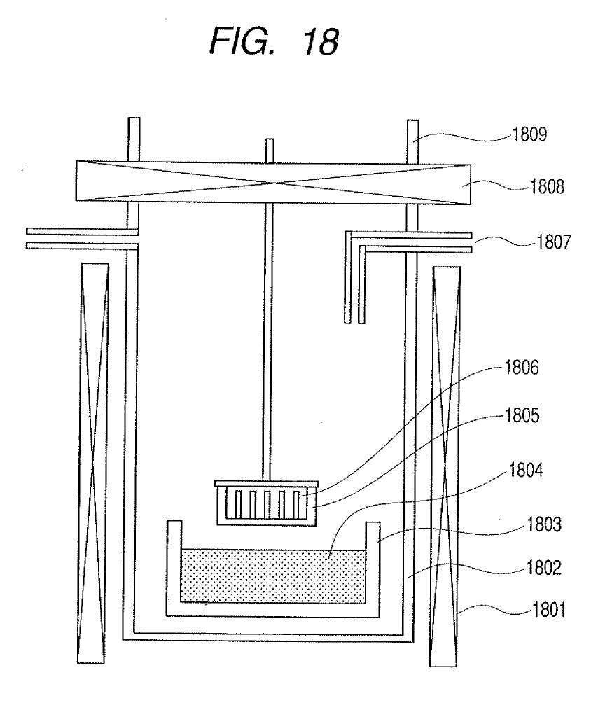

FIG. 18 is a sectional view showing a liquid phase growth apparatus suitable to embody the present invention. In FIG. 18, the liquid phase growth apparatus includes a heater 1801, a quartz tube 1802, a crucible 1803, a carrier 1805, a gas introducing tube 1807, a gate valve 1808, and a load lock chamber 1809. Reference numeral 1804 denotes a melt and 1806 denotes bases. First, the crucible 1803 is heated by the cylindrical heater 1801 that surrounds the crucible 1803. Therefore, silicon is melted up to saturation at a temperature of about 600° C. to 1200° C., which is set according to a kind of melt, thereby forming the melt 1804. In this embodiment, a melted silicon material may be metallurgical grade silicon. Subsequently, the bases 1806, each of which is made of polycrystalline silicon are arranged in parallel at intervals of 10 mm in the carrier 1805 and immersed into the melt 1804. In FIG. 18, five bases are used. Tens of bases or hundreds of bases can be also grown according to a size of the crucible. After the bases 1806 are immersed into the melt 1804, the melt is cooled. When the melt is cooled, silicon which is not melted is deposited on the bases 1806. Since each of the bases is made of polycrystalline silicon, the deposited silicon (layer) follows the bases and becomes polycrystalline. Cooling is slowly performed at constant speed in many cases. Such cooling is called a slow cooling method. In addition to the slow cooling method, the liquid phase growth method includes a method which is called a temperature difference method. In the temperature difference method, both a solid of solute such as silicon and a base are immersed into a melt. The solute is maintained at a relatively high temperature and the base is maintained at a relatively low temperature, so that the solute is eluted and diffused from the surface of the solid of solute to grow the solute on the base. Since a temperature of each part can be always kept constant, the temperature difference method is preferably used to grow compound semiconductor required for particularly the uniformity of the grown film in the film thickness direction. The temperature difference method is suitably applied to grow silicon. The conductivity type and resistivity of the polycrystalline silicon layer are influenced by the melt. Indium, gallium, aluminum, and the like each are a p-type dopant. When such metal is used for the melt, the dopant is solubilized into silicon in many cases, so that the silicon becomes a p-type. Among indium, gallium, aluminum, and the like, indium has low solubility to silicon, so that the conductivity is easy to control. Although solubility of tin to silicon is slightly accepted, tin is electrically inert and the conductivity is easy to control because of a IV group element. When the melt is used, a dopant such as boron, aluminum, gallium, phosphorus, or antimony is melted together with the silicon into the melt to perform liquid phase growth. Therefore, the p-type and the n-type can be freely controlled.

### (Facet)

When the liquid phase growth is performed on the base 201 made of polycrystalline silicon, a specific plane orientation, particularly, a flat surface (facet surface) having a (111) plane is easy to produce on the surface of the grown crystalline silicon. This may be because the liquid phase growth occurs with a state close to thermal equilibrium. For example, as disclosed in Japanese Patent Application Laid-Open No. H09-129907, when the plane orientation of the surface of a crystal grain in the base 201 is a (100) plane, unevenness formed by facet surfaces of the polycrystalline silicon layer 202 grown on the crystal grain may be a pyramid shape. When a crystal grain has a plane orientation of (111) plane, the facet surface of the polycrystalline silicon layer 202 grown on the crystal grain may be flattened relative to the surface of the base 201.

The surface of the base 201 is composed of a large number of crystal grains having different plane orientations. Therefore, the orientation of the facet surface produced by the growth changes for each crystal grain, so that the orientations become random. Minute unevenness having a pitch of several μm to several tens μm and an uneven difference of several tens nm to several tens μm is formed on the surface of the polycrystalline silicon layer 202 from shapes surrounded by a plurality of facet surfaces. From the above-mentioned reason, it is expected that the unevenness fundamentally becomes a flat shape, a groove shape (V-groove), a triangular pyramid shape, or a quadrangular pyramid shape.

According to findings from experiments conducted by the present inventors, the shape of the unevenness formed on the surface of the polycrystalline silicon by the plurality of facet surfaces is typically divided into two types.

According to a first shape type of the unevenness formed by the plurality of facet surfaces, each concave portion has a groove shape (V-groove shape). Conversely, a cross section of convex portions is a shape of triangular mountains. FIG. 10 shows a schematic view showing the first shape type.

In FIG. 10, reference numeral 1001 denotes polycrystalline silicon formed by growth and 1002 denotes a facet surface. Unevenness whose cross section is triangles is formed by opposite facet surfaces. FIG. 10 shows the unevenness formed with a uniform size, a constant pitch, and the same shape. Actually, the size, the pitch, and the shape each have a range and are random. Note that, in the same crystal grain, only unevenness having a groove shape is formed and unevenness having a shape different from the groove shape is not formed. The pitch of triangles and the uneven difference of the unevenness can be controlled according to a growth condition. The growth condition includes a temperature profile in the case where a melt is slowly cooled, a density of the melt, a growth timer and a base locating method. With respect to the temperature profile, there are (1) a pattern in which the temperature of the melt is reduced at constant rate, (2) a pattern in which the temperature of the melt is reduced stepwise, (3) a pattern in which the temperature of the melt is reduced to a temperature lower than a supersaturation temperature from the beginning, (4) a combination of those patterns, and the like. According to observations from experiments conducted by the present inventors, generally, when a temperature gradient increases or when the growth time lengthens, the uneven difference of the unevenness becomes larger.

When the above-mentioned condition is selected, the unevenness having the pitch of several μm to several tens μm and the uneven difference of several tens nm to several tens μm is obtained. A tilt angle formed by the facet surface and the base which compose the unevenness is changed according to the plane orientation of each crystal grain on the surface of the base. Therefore, various tilts having about 5° to 45° are obtained.

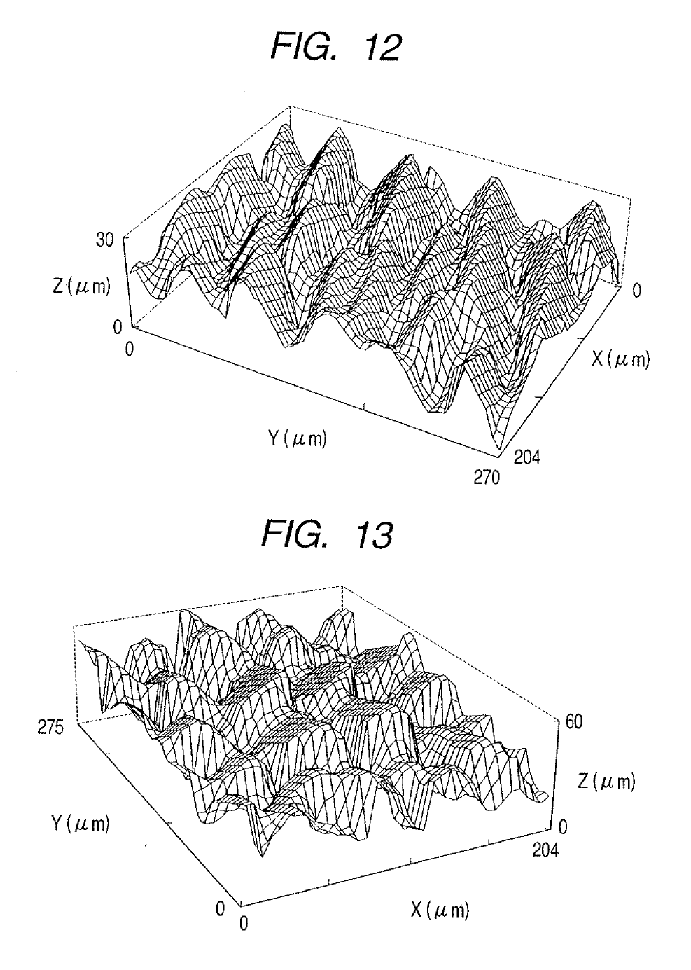

Thus, it is expected that groove-shaped unevenness whose cross section is the shape of triangles is formed by opposing two facet surfaces each having a (111) orientation, which are grown in the plane orientation of the crystal grain on the base. FIG. 12 shows an example of a three-dimensional contour drawing taken by three-dimensionally measuring a part of an actually grown sample using a laser microscope. FIG. 12 shows observations with a visual field of about 270 μm wide and about 200 μm high. An optical effect of such a shape is examined using commercially available ray tracing simulation software. An application “Light tools” is used as the simulation software. For simplification, a silicon layer having the shape shown in FIG. 12 is prepared as a three-dimensional model and an anti-reflection film is provided on the surface of the silicon layer. A thickness of the silicon layer is set to 40 μm. Although the three-dimensional model is not a single cell of amorphous silicon in which a rear electrode is provided, the model is simplified to estimate a general effect of an unevenness surface.

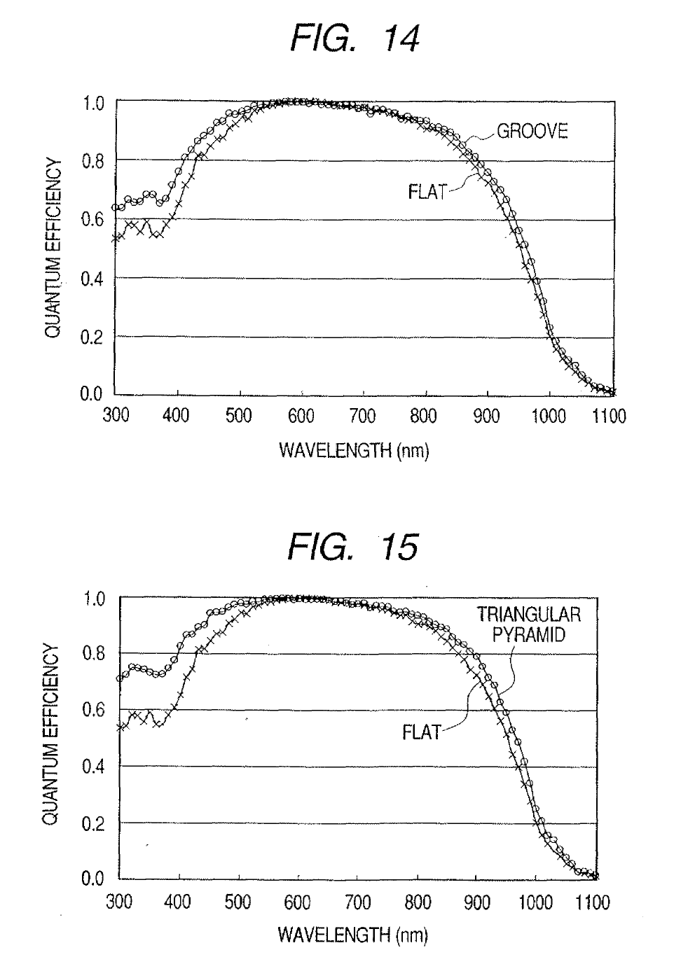

Light having a wavelength and intensity in a solar spectrum, which are specified in Japanese Industrial Standard (JIS) is emitted from the top of the model to the silicon layer. Energy absorbed in the silicon layer is observed by a receiver (photo detector). A ratio between absorption energy and emission energy is calculated and a plot of the ratio is prepared based on wavelengths. For comparison, the case where the silicon layer has a flat surface is also simulated. FIG. 14 shows a result obtained by the simulation. As is apparent from FIG. 14, a spectral response in the case of the groove shape is larger than that in the case of the flat surface. Thus, a solar cell having a preferable characteristic such as a large short-circuit current value is obtained.

That is, even when light incident on the surface having such a shape is reflected thereon, reflection light is incident on an opposed facet surface. Therefore, an effect capable of utilizing light again is expected. The model has the single cell structure. Even when a double cell structure or a triple cell structure is used, the same effect as in FIG. 14 is obtained with respect to a sum of spectral responses of respective cells.

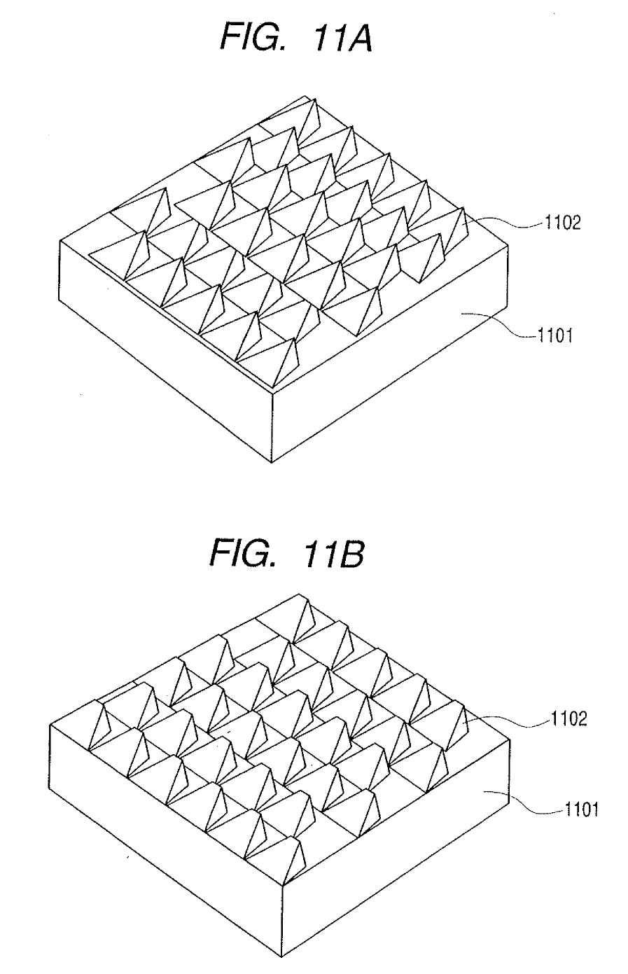

According to a second shape type of the unevenness formed on the surface of the polycrystalline silicon by the plurality of facet surfaces, each convex portion is formed in a triangular pyramid or pentahedron shape by the plurality of facet surfaces. FIGS. 11A and 11D are schematic views showing the second shape type. In FIGS. 11A and 11B, reference numeral 1101 denotes polycrystalline silicon and 1102 denotes a facet surface. The triangular pyramid or pentahedron (including a base surface) shape may be produced by three or four facet surfaces each having the (111) orientation, which are formed in the plane orientation of the crystal grain of the base. In FIG. 11B, each convex portion is a pentahedron and does not become a pyramid shape. This is because an edge line is produced by bonding the apexes of two adjacent quadrangular pyramids to each other during the progress of liquid phase growth. The pitch of triangular pyramids or pentahedrons and the uneven difference of the unevenness can be controlled according to a growth condition as in the case of the groove-shaped unevenness. Therefore, the unevenness having the pitch of several μm to several tens μm and the uneven difference of several tens nm to several tens μm is obtained.

FIG. 13 shows an example of a three-dimensional contour drawing taken by three-dimensionally measuring a part of an actually grown sample using a laser microscope as in the case of the groove-shaped unevenness. Although the shape of the apex is not cleared in FIG. 13 because of the limited resolution of the laser microscope, FIG. 13 may show a shape corresponding to at least one of the shapes shown in FIGS. 11A and 11B. FIG. 15 shows a result obtained by simulating an optical effect of such a shape as in the above-mentioned simulations. As is apparent from FIG. 15, a spectral response in the case of the triangular pyramid or pentahedron shape is larger than that in the case of the flat surface. Thus, a solar cell having a preferable characteristic such as a large short-circuit current value is obtained.

That is, even when light incident on the surface having such a shape is reflected thereon, reflection light is incident on an opposed facet surface. Therefore, an effect capable of utilizing light again is expected.

The groove-shaped unevenness, the triangular pyramid or pentahedron shaped unevenness, and the flat surface may be distributed in single liquid-phase-grown polycrystalline silicon at a predetermined ratio. The predetermined ratio may coincide with the plane orientation distribution of the crystal grains. The tilt angle and uneven difference of the unevenness are also distributed with predetermined ranges. Therefore, it is necessary to select a manufacturing condition that most preferable unevenness is obtained by the optimization of various conditions.

According to the photovoltaic device of the present invention, the metallic electrode layer 203, the oxide semiconductor layer 204, the n-layer 205, the i-layer 206, the p-layer 207, and the transparent electrode layer 208 are deposited along the shape of the unevenness on the surface of the polycrystalline silicon layer 202. Therefore, with respect to the surface shape of each of the layers on the light incident side, unevenness having an uneven difference, a pitch, and a tilt which are substantially equal to those of the polycrystalline silicon layer 202 is formed on the surface of each of the layers.

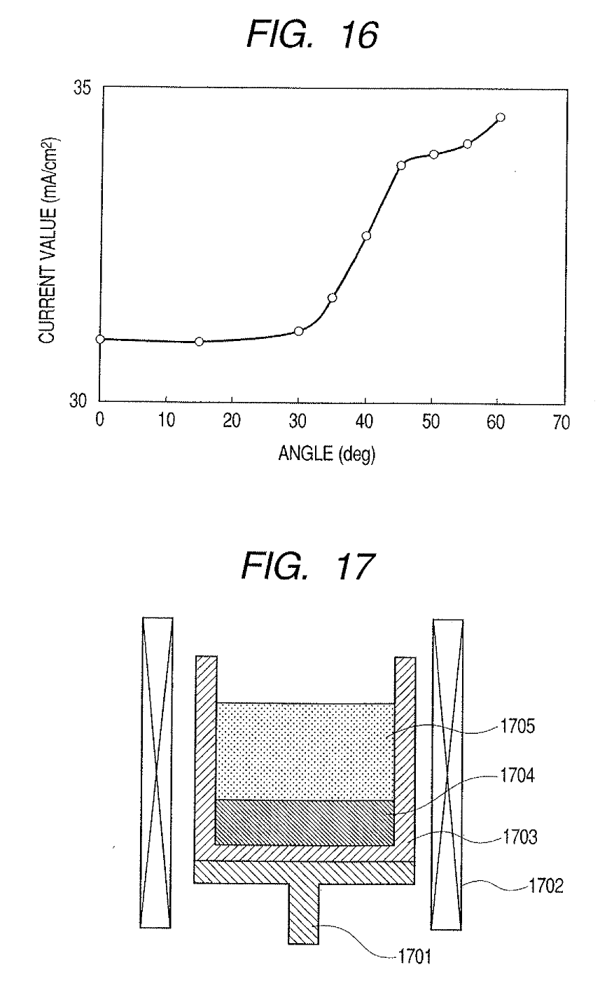

Light scattering is caused on the surface of the transparent electrode layer 208 by the unevenness, thereby reducing a reflectance. A change in light utilization efficiency according to a tilt angle of the facet surface 1002 composing the unevenness of the polycrystalline silicon layer 1001 as shown in FIG. 10 is simulated using optical simulation software. A three-dimensional model is the same as that used for the simulation shown in FIG. 14. According to the simulation, a product of an absorption factor of light energy at each wavelength and the number of photons is summed to calculate a short-circuit current value of a solar cell. FIG. 16 shows a result obtained from the simulation. As shown in FIG. 16, when the tilt angle is equal to or larger than 30°, an effect of increasing the current value of the solar cell is obtained. This reason may be as follows. After light is incident on a facet surface, a reflection part of the light is incident on an adjacent facet surface to allow the reflection part to enter the silicon layer again, thereby achieving the reuse of light. When the tilt angle is equal to or larger than 30°, the amount of light incident on the adjacent facet surface increases. The simulation is on the precondition that the tilts of the facet surfaces adjacent to each other are symmetric with respect to a vertical line. In the asymmetric case, a tilt angle that the effect appears may be changed. However, the tilt angle that the effect appears may be fundamentally equal to that in the simulation. The tilt angle is determined according to not only the liquid phase growth condition but also the plane orientation of the crystal grains of the base 201. It is important to form the above-mentioned unevenness such that the crystal grains of the base 201 have a preferable plane orientation. In a slicing step after an ingot is produced, a percentage of crystal grains having the preferable plane orientation is varied according to a slicing direction (longitudinal direction or lateral direction) of the ingot. Therefore, the ingot may be sliced in the selected slicing direction as appropriate.

The uneven difference of the unevenness can be controlled according to the liquid phase growth condition, so that unevenness having a selected desirable size can be formed. When the silicon is used for a solar cell substrate, a preferable shape of the silicon is determined based on an interrelationship among the above-mentioned optical effect, productivity in a post-process such as screen printing, and a growth time. That is, a large tilt is advantageous in view of light scattering. However, when a semiconductor layer and a transparent electrode are formed, the large tilt and extremely large unevenness are not preferable because of a reduction in film coverage. Similarly, even when an electrode is formed by screen printing, a screen plate is likely to break. When an uneven surface is sucked and an electrode is printed on a rear surface, the uneven surface is hard to suck. Therefore, large unevenness is not preferable. In addition, the formed electrode is likely to cause step disconnection and contact of the electrode deteriorates, so that too large unevenness is not preferable. In the case where a polycrystalline silicon layer formed by liquid phase growth is used as an active layer, when the uneven difference of the unevenness is too larger than the entire film thickness, the amount of light absorption reduces because of a reduction in substantial thickness of the active layer. In view of the above description, the preferable unevenness is determined as appropriate. A known desirable value is suitably used for the preferable shape of the unevenness. That is, it is preferable that the uneven difference is 0.05 μm to 10 μm. When the uneven difference is smaller than 0.05 μm, a geometrical-optical anti-reflection effect is not obtained because such an uneven difference is a value smaller than the wavelength of light. When the uneven difference is larger than 10 μm, as described above, there is the case where the screen plate is damaged in screen printing for electrode formation or the electrode is disconnected at step, with the result that the electrode is hard to form.

In the above-mentioned simulation, the unevenness effect on the light incident side is examined. For more details, light incident on the transparent electrode layer 208 is scattered on the unevenness surface and then scattered on the boundary between the metallic electrode layer 203 and the oxide semiconductor layer 204, thereby causing multiple reflection. Therefore, an effect of increasing an optical path length is obtained. FIG. 6 is a schematic view showing such an optical path of incident light. FIG. 6 shows two behaviors. According to the first behavior, after a light beam 609 incident on a facet surface of the solar cell reaches a transparent electrode 608, incident light is scattered on a metallic electrode 603 and absorbed in an i-layer 606 again. According to the second behavior, a part of the incident light beam 609 is reflected on the transparent electrode 608 and then incident on an adjacent facet surface. After that, light incident on the adjacent facet surface is incident on the i-layer 606 and absorbed therein again. Note that reference numeral 601 denotes a base, 602 denotes polycrystalline silicon, 604 denotes an oxide semiconductor layer, 605 denotes an n-layer, and 607 denotes a p-layer. As is apparent from FIG. 6, even in the case of the rear reflection, the groove-shaped unevenness and the triangular pyramid or pentahedron shaped unevenness have an effect of scattering light and increasing the optical path length.

### (Semiconductor)

A structure having a pin-type semiconductor junction is required for the semiconductor layers 205, 206, and 207. A semiconductor such as a-Si, a-SiGe, or μc-Si is preferably used as a material of each of the semiconductor layers. The semiconductor junction may be used for not only the single cell but also a tandem cell in which a plurality of cells are stacked and a triple cell.

With respect to a specific structural example of the tandem cell, there are, for example, three structures. According to a first structure, a top layer and a bottom layer each have a pin-junction in which an i-layer is made of a-Si. The top layer and the bottom layer are stacked. According to a second structure, a top layer has a pin-junction in which an i-layer is made of a-Si. A bottom layer has a pin-junction in which an i-layer is made of a-SiGe. The top layer and the bottom layer are stacked. According to a third structure, a top layer has a pin-junction in which an i-layer is made of a-Si. A bottom layer has a pin-junction in which an i-layer is made of μc-Si. The top layer and the bottom layer are stacked.

With respect to a specific structural example of the triple cell, there are, for example, three structures. According to a first structure, a top layer and a middle layer each have a pin-junction in which an i-layer is made of a-Si. A bottom layer has a pin-junction in which an i-layer is made of a-SiGe. The top layer, the middle layer, and the bottom layer are stacked. According to a second structure, a top layer has a pin-junction in which an i-layer is made of a-Si. A middle layer has a pin-junction in which an i-layer is made of a-SiGe. A bottom layer has a pin-junction in which an i-layer is made of a-SiGe. The top layer, the middle layer, and the bottom layer are stacked. According to a third structure, a top layer has a pin-junction in which an i-layer is made of a-Si. A middle layer and a bottom layer each have a pin-junction in which an i-layer is made of μc-Si. The top layer, the middle layer, and the bottom layer are stacked.

A known method disclosed in Japanese Patent Application Laid-Open No. H10-150209 is preferably used as a method of producing the a-Si and the μc-Si. More specifically, a high frequency power source having a frequency of 13.56 MHz is used for the a-Si. In the case of the μc-Si, a VHF power source having a frequency of 30 MHz to 600 MHz is used in addition to the high frequency power source. Each film is formed by a plasma CVD method.

### (Transparent Electrode Layer)

Silicon has a high refraction index of about 3.4 and a reflectance of the silicon is higher than that of air, so that it is necessary to form a suitable anti-reflection layer on the surface of the silicon. In addition, a sheet resistance of the semiconductor layer 207 is relatively high, so that it is necessary to serve a function of collecting energy by a reduction in sheet resistance in addition to an anti-reflection function. Therefore, the transparent electrode layer 208 which is transparent and has preferable conductivity is required. A known transparent electroconductive film which is made of a material such as ITO, SnO₂, or In₂O₃ and has a thickness of about 60 nm to 90 nm is preferably used as the transparent electrode layer 208. A sputtering method, an evaporation method, or the like is generally used as a deposition method for the transparent electrode layer 208.

### (Metallic Electrode Layer)

A material having a preferable light reflectance and large conductivity is preferably used for the metallic electrode layer 203. More specifically, a material such as silver or aluminum is used. A thickness of the metallic electrode layer 203 is preferably about 0.1 μm to 3 μm.

### (Oxide Semiconductor Layer)

The oxide semiconductor layer 204 is used to prevent migration in the metallic electrode layer 203 and to increase reflection thereon. More specifically, a material is selected from zinc oxide, tin oxide, ITO, and the like.

### Embodiment 2

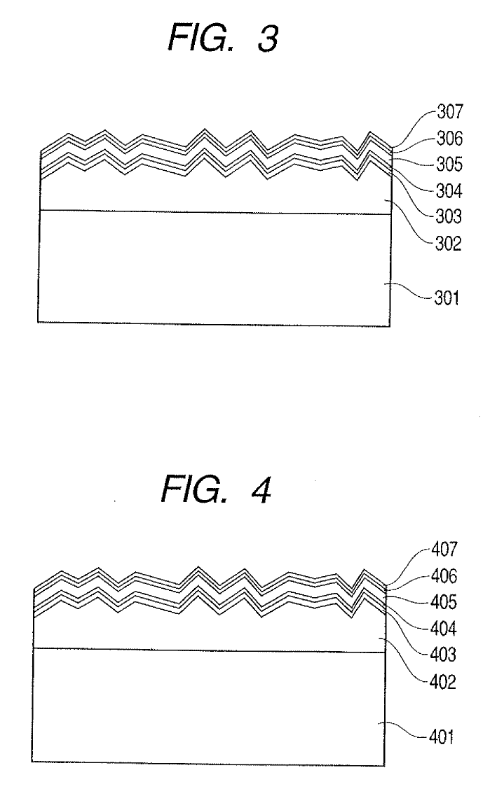

FIGS. 3 and 4 each show a double cell in Embodiment 2. According to a structure shown in FIG. 3, an emitter layer 303 is formed on a polycrystalline silicon layer 302 located on a base 301 to compose a polycrystalline pn-junction. A pin-junction composed of an n-layer 304, an i-layer 305, and a p-layer 306 is produced on the emitter layer 303. As a result, a photovoltaic device of a double cell is obtained as the entire structure. Reference numeral 307 denotes a transparent electrode layer. In such a structure, the base 301 has a conductivity type of n⁺, the polycrystalline silicon layer 302 has a conductivity type of n⁻, and the emitter layer 303 has a conductivity type of p⁺. The polycrystalline silicon layer 302 and the emitter layer 303 form the pn-junction and serve for a bottom cell. The n-layer 304, the i-layer 305, and the p-layer 306 form the pin-junction and serve for a top cell. Therefore, the photovoltaic device of the double cell is obtained as the entire structure. FIG. 4 shows a structure in which a conductivity type on the light incident side is an n-type. A base 401 is set to a conductivity type of p⁺. A polycrystalline silicon layer 402 having a conductivity type of p⁻ is provided on the base 401. An emitter layer 403 having a conductivity type of n⁺ is provided on the polycrystalline silicon layer 402. An nip-junction composed of a p-layer 404, an i-layer 405, and an n-layer 406 is produced on the emitter layer 403. Reference numeral 407 denotes a transparent electrode layer. In such a structure, the polycrystalline silicon layer 402 and the emitter layer 403 form the pn-junction and serve for a bottom cell. The p-layer 404, the i-layer 405, and the n-layer 406 compose the nip-junction and serve for a top cell. Therefore, the photovoltaic device of the double cell is obtained as the entire structure. One of the photovoltaic devices shown in FIGS. 3 and 4 is desirably selected as appropriate based on characteristics such as manufacturing ease and conversion efficiency.

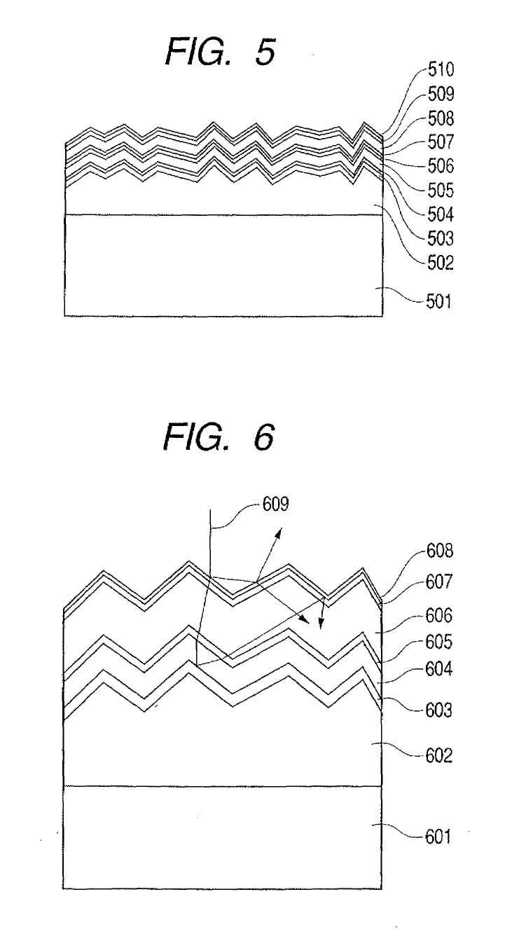

FIG. 5 shows a solar cell having a triple cell structure according to a modified example of this embodiment. In FIG. 5, two pin-junctions are produced. A middle layer is composed of an n-layer 504, an i-layer 505, and a p-layer 506. A top layer is composed of an n-layer 507, an i-layer 508, and a p-layer 509. Note that reference numeral 501 denotes a base, 502 denotes polycrystalline silicon, 503 denotes an emitter layer, and 510 denotes a transparent electrode layer.

### (Liquid Phase Growth)

In this embodiment, the polycrystalline silicon layer formed by the liquid phase growth is used as the active layer of the solar cell. Metallurgical grade silicon containing a large number of impurities is not suitable as a silicon material to be melted in the liquid phase growth. However, semiconductor grade (purity of about 10N to 11N) silicon is not required. Semiconductor grade (purity of about 6N to 7N) silicon may be used. The resistivity of the polycrystalline silicon layer is preferably about 0.1 Ω·cm to 10 Ω·cm. When the resistivity is higher than 10 Ω·cm, an n⁺/p-junction (or p⁺/n-junction) with the emitter layer is not sufficiently produced, an open current voltage particularly reduces. Conversely, when the resistivity is lower than 0.1 Ω·cm, a depletion layer does not sufficiently expand and recombination of carriers increases, so that a short-circuit photo-current particularly reduces. It is necessary to set the base and the polycrystalline silicon layer to the same conductivity type so as not to produce a junction reverse to a junction produced by the emitter layer. A resistance of the base made of metallurgical grade silicon is likely to reduce. However, with respect to merits of the base having a low resistance, sensitivity of the solar cell in a long wavelength region is improved by a back surface field effect and electrical contact with the rear electrode is easily made. In the present invention, the base contains a dopant element having a high concentration. In particular, the metallurgical grade silicon is used as a raw material, heavy metal impurities which are not removed are contained in the base.

Before the beginning of the liquid phase growth, generally, the temperature of the melt 1804 is temporarily set to a value higher than a saturation temperature of silicon in the apparatus as shown in FIG. 18 to obtain an unsaturation state. After that, the base 1806 is immersed into the melt 1804 to melt a portion of the base in the melt, so that the surface of the base is adapted for the melt. The base made of the metallurgical grade silicon is not preferable to use because impurities in the base are melted into the melt. The surface of the base is suitably processed by etching and a flow of a reducing gas such as hydrogen is formed in a container for housing the base and the crucible. In such a case, even when the temperature of the melt is reduced from the saturation temperature of silicon by several degrees centigrade to more than tens degrees centigrade and then the base immersed into the melt, the surface of the base is adapted for the melt. Therefore, impurities are not melted into the melt.

When such a base is used, the dopant element and the heavy metal impurities are likely to diffuse from an exposed surface of the base into a processing apparatus in a solar cell manufacturing process, thereby influencing characteristics of a manufactured solar cell. In particular, in a thermal diffusion step of forming the emitter layer (n⁺-type layer in the case where the polycrystalline silicon layer has a p-type) on the surface at a high temperature, the influence is likely to appear. In view of preventing impurity diffusion, it is desirable to cover the entire surface of the base with a high purity polycrystalline silicon layer in liquid phase growth. However, when the rear surface of the base is covered with a polycrystalline silicon layer having a relatively high resistance, electrical contact on the rear side is hard to make. Thus, liquid phase growth may be performed on the base so as to expose a predetermined region on the rear surface of the base. On the other hand, the front surface and end surfaces of the base may be completely covered with the high purity polycrystalline silicon layer. When the produced substrate is subjected to the solar cell manufacturing process, the diffusion of impurities can be suppressed by using a method of providing a cover on an exposed region or a method of overlapping two substrates with a state in which the rear surfaces thereof face to each other. Since the exposed region has a low resistance, the electrical contact with the base can be easily made.

### (Formation of Emitter Layer)

With respect to a method of forming the emitter layer 303, there are a method of growing a thin silicon layer doped with an impurity for a conductivity type reverse to that of the polycrystalline silicon layer 302 at a high concentration on the surface of the polycrystalline silicon layer 302 subjected to the liquid phase growth and a method of changing a conductivity type of an uppermost surface having a thickness of several hundreds of nm by performing thermal diffusion of a dopant or ion implantation on the surface of the polycrystalline silicon layer. An application solution containing phosphorus for coating or a P₂O₅ layer formed on the surface of the polycrystalline silicon by oxidation using an inert gas containing POCl₃ can be utilized as an n-type diffusion source. A B₂O₃ layer formed on the surface of the polycrystalline silicon by oxidation using an inert gas containing BBr₃ can be utilized as a p-type diffusion source. A target of bonding depth of the emitter layer is about 0.1 μm to 0.5 μm and a target of a surface sheet resistance is about 10 Ω/square to 100 Ω/square. When such an emitter layer is obtained by the thermal diffusion, it is necessary to perform treatment at a temperature of about 700° C. to 900° C. for several minutes to several tens of minutes. However, as described above, impurities such as boron, phosphorus, and heavy metal, which are contained in the base are likely to diffuse. Boron and phosphorus have a short diffusion length in a solid phase. A concentration of the heavy metal is reduced by unidirectional solidification. Therefore, a problem is unlikely to occur. When a CVD furnace is used or a dopant is thermally diffused in a diffusion furnace in the formation of the emitter layer, the impurities are likely to diffuse from a vapor phase.

In contrast to this, two bases, in each of which at least the front surface and end surfaces are covered with the high purity polycrystalline silicon layer are overlapped with a state in which the rear surfaces face to each other, and placed in a CVD furnace or a diffusion furnace. Therefore, the risk of diffusion of the impurities in the vapor phase can be minimized.

### (Oxide Semiconductor Layer)

In this embodiment, the bottom cell has a polycrystalline pn-junction and the top cell or the middle cell has a pin-junction of amorphous silicon. The oxide semiconductor layer may be desirably formed as a buffer layer in a boundary between the pn-junction and the pin junction to obtain a preferable ohmic property. An oxide semiconductor in Embodiment 1 is preferably used as a material for obtaining the preferable ohmic property.

### (Semiconductor)

A pin-type semiconductor junction is preferable for the semiconductor layers 304, 305, 306, 504, 505, 506, 507, 508, and 509. A semiconductor such as amorphous silicon or micro-crystalline silicon is preferably used as a material of each of the semiconductor layers. The semiconductor junction may be used for not only the single cell but also a tandem cell in which a plurality of cells are stacked and a triple cell.

With respect to a specific structural example of the tandem cell, there are, for example, three structures. According to a first structure, a top layer and a bottom layer each having a pin-junction in which an i-layer is made of a-Si are stacked. According to a second structure, a top layer has a pin-junction in which an i-layer is made of a-Si. A bottom layer has a pin-junction in which an i-layer is made of a-SiGe. The top layer and the bottom layer are stacked. According to a third structure, a top layer has a pin-junction in which an i-layer is made of a-Si. A bottom layer has a pin-junction in which an i-layer is made of μc-Si. The top layer and the bottom layer are stacked.

With respect to a specific structural example of the triple cell, there are, for example, three structures. According to a first structure, a top layer and a middle layer each have a pin-junction in which an i-layer is made of a-Si. A bottom layer has a pin-junction in which an i-layer is made of a-SiGe. The top layer, the middle layer, and the bottom layer are stacked. According to a second structure, a top layer has a pin-junction in which an i-layer is made of a-Si. A middle layer has a pin-junction in which an i-layer is made of a-SiGe. A bottom layer has a pin-junction in which an i-layer is made of a-SiGe. The top layer, the middle layer, and the bottom layer are stacked. According to a third structure, a top layer has a pin-junction in which an i-layer is made of a-Si. A middle layer and a bottom layer each have a pin-junction in which an i-layer is made of μc-Si. The top layer, the middle layer, and the bottom layer are stacked.

When the i-layer of the middle layer is made of micro-crystalline silicon and the i-layer of the top layer is made of amorphous silicon, the separation of absorption wavelengths is possible, thereby obtaining a preferable characteristic.

A preferable thickness of each of the bottom layer and the top layer is designed such that values of currents generated by absorbable light determined from optical absorption coefficients of the respective layers become equal to each other. More specifically, the thickness of the bottom layer is preferably about 3 μm to 10 μm and the thickness of the i-layer of the top layer is preferably about 0.1 μm to 1 μm.

### (Formation of Rear Electrode and Isolation of Emitter Layer)

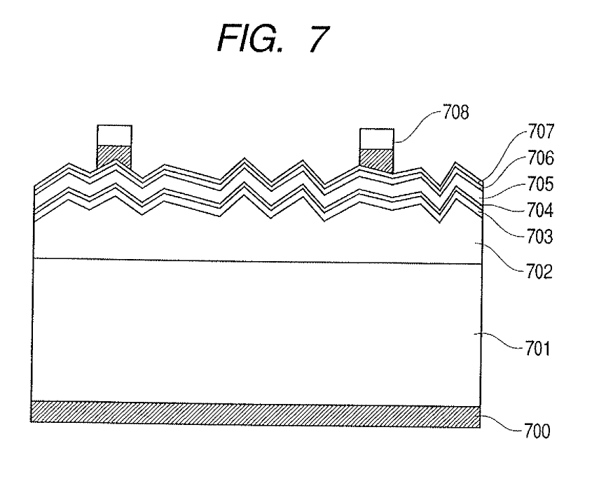

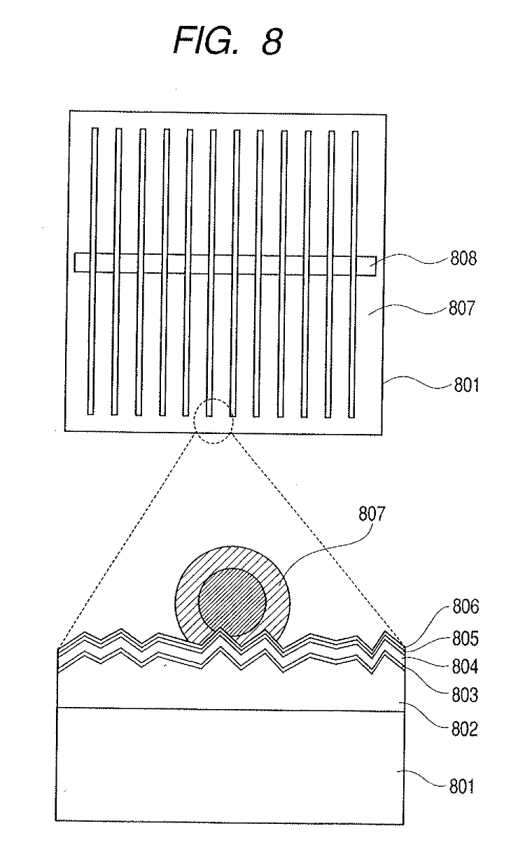

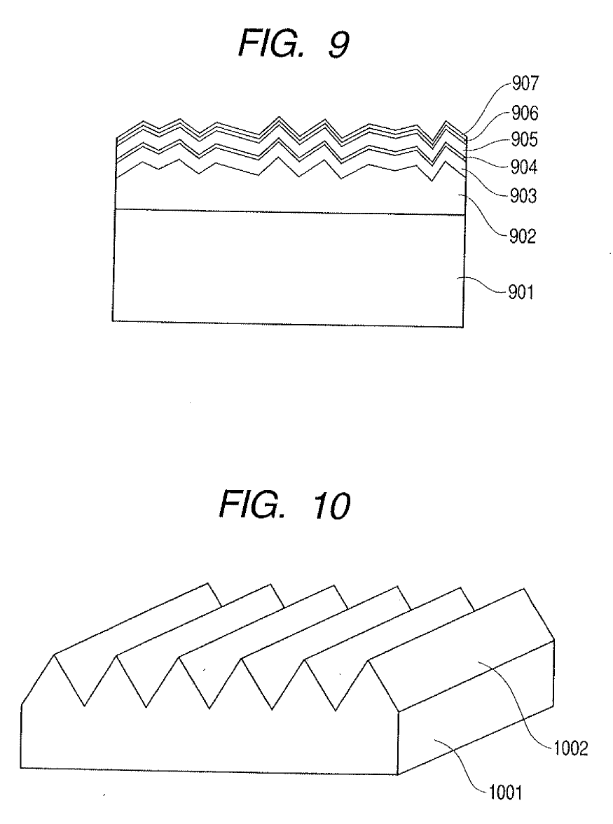

Next, an example in which a rear electrode and a front surface grid are formed will be described with reference to FIG. 7. In FIG. 7, a photovoltaic device includes a rear electrode layer 700, a base 701 made of low purity silicon, a polycrystalline silicon layer 702, an emitter layer 703, an n-layer 704, an i-layer 705, a p-layer 706, a transparent electrode layer 707 and grid electrodes 708.

In a general crystalline silicon solar cell, electrical contact is made on the rear side. In particular, when the polycrystalline silicon layer has a p-type, an aluminum paste is printed and baked to form the rear electrode layer 700 in many cases. When the aluminum paste is baked, the aluminum paste is contracted to distort a substrate in many cases. In particular, when the rear electrode layer is formed on the entire rear surface, the substrate is significantly distorted. When the distortion becomes a problem, the rear electrode layer 700 may be formed in a separate pattern without the formation on the entire rear surface as shown in FIG. 7.

As described above, the emitter layer 703 is formed on the surface of the polycrystalline silicon layer. When the emitter layer 703 makes contact with the rear electrode layer 700 or the front surface of the baser a photo-current leaks, thereby significantly deteriorating a solar cell characteristic. When at least the front surface and end surfaces of the base are substantially covered with the polycrystalline silicon layer, the risk of leakage is small. When substrates are processed with a state in which the rear surfaces thereof face to each other in a CVD process or thermal diffusion process for forming the emitter layer, particularly, the emitter layer is hard to reach the rear surfaces. Therefore, the risk of leakage further reduces. However, when a leakage between the emitter layer 702 and the rear electrode layer 700 or the base 701 is particularly prevented, the isolation is preferably performed as follows. When the emitter layer is formed, a diffusion source of a dopant is formed by printing using a pattern excluding a substrate peripheral region. Alternatively, the emitter layer in the substrate peripheral region is removed by etching. Alternatively, the surface of the substrate peripheral region is scribed. When the emitter layer in the substrate peripheral portion is etched or scribed, it is desirable to substantially remove the emitter layer in a predetermined region. When the emitter layer is removed until the surface of the base is exposed, the leakage is likely to occur. Thus, it is necessary to control a removal depth. When a substantially insulating anti-reflection film such as a silicon nitride film is used, the isolation is performed before the formation of the anti-reflection film because a leak prevention effect is further improved.

### (Grid Electrode)

Grid electrodes 708 for taking photo-currents are formed on the surface of the transparent electrode layer 707. Since the grid electrodes 708 become blocks against incident light, it is desirable to minimize a width of the grid electrode and the number of grid electrodes. However, since currents concentratedly flow, a low resistance is preferable. It is necessary to make preferable electrical connection between the grid electrodes 708 and the transparent electrode layer 707. In view of this, a pattern of a silver paste is screen-printed to form the grid electrodes 708 in many cases. The grid electrodes 708 are generally thin and have a high resistance. Therefore, the grid electrodes 708 are coated with solder to reduce resistances thereof. In each of the grid electrodes 708 shown in FIG. 7, a lower portion indicates a silver paste electrode and an upper portion indicates solder.

With respect to another preferable structure of the grid electrode, there is a known metallic wire coated with an electroconductive resin as described in Japanese Patent Application Laid-Open No. H08-236796.

FIG. 8 is a plan view and partially enlarged cross sectional view, showing a solar cell using a grid wire. In FIG. 8, a solar cell includes a base 801 made of low purity silicon, a polycrystalline silicon layer 802, an n-layer 803, an i-layer 804, a p-layer 805, a transparent electrode layer 806, wire grids (grid electrodes) 807, and a bus bar 808.

Each of the wide grids 807 includes a core wire made from a metallic wire and an electroconductive resin coating member to which an electroconductive filler is added.

For example, a material which has a low electrical resistance and is industrially stably supplied as a wire member is preferably used as a material of the metallic wire, such as copper, silver, gold, platinum, aluminum, molybdenum, or tungsten. A thin surface metallic layer may be formed to improve the electrical connection, for example. In particular, copper is used for the metallic wire, the surface is oxidized to increase a resistance. When the electroconductive particle of the coating layer is graphite or a metal oxide, a contact resistance increases. In order to prevent such a phenomenon, the surface metallic layer is used. A noble metal resistant to corrosion, such as silver, palladium, an alloy of silver and palladium, or gold, or a metal having a high corrosion resistance, such as nickel or tin is preferable for the surface metallic layer. A plating method or a cladding method is preferably used as the method of forming the surface metallic layer. The surface metallic layer may be coated with an electroconductive resin produced by dispersing the metal as a filler to a resin. A thickness of coating is determined as necessary. For example, in the case of a metallic wire having a circular cross section, the thickness is preferably 1% to 10% of a diameter thereof.

The cross sectional shape of the metallic wire is preferably a circle. The cross sectional shape may be a square and is suitably selected as necessary. The diameter of the metallic wire is selected for design so as to minimize a sum of an electrical resistance loss and a shadow loss. More specifically, a copper wire having a diameter of 25 μm to 1 mm is preferably used. More preferably, when the diameter is set to 25 μm to 200 μm, a solar cell having high efficiency is obtained. When the diameter is smaller than 25 μm, the wire is likely to break. Manufacturing is hard and an electrical loss increases. When the diameter is larger than 200 μm, the shadow loss increases and unevenness on the surface of the solar cell becomes larger. In sealing such as lamination, it is necessary to thicken a filling member such as EVA. The electroconductive adhesive for bonding the metallic wire of the photovoltaic device is obtained by dispersing electroconductive particles and a polymer resin. A resin which is capable of easily forming an application film on the metallic wire and has superior workability, flexibility, and a superior weather resistance is preferable as the polymer resin. With respect to a preferable material of such a thermosetting resin, there are, for example, an epoxy resin, an urethane resin, a phenol resin, a polyvinylformal resin, an alkyd resin, or a resin produced by modifying those. In particular, the urethane resin is used as an insulating coating material for enamel wire and a superior material on flexibility and productivity. With respect to a preferable thermoplastic resin, there are a phenoxy resin, a polyamideimide resin, polyamide, a melanin resin, butyral, a fluorine resin, acrylic, styrene, polyester, and the like.

The electroconductive particle is a pigment for imparting electroconductivity. For example, graphite, carbon black, In₂O₃, TiO₂, SnO₂, ITO, ZnO, or an oxide semiconductor material in which a suitable dopant is added to one of those is preferably used as a specific material. It is required that a particle size of the electroconductive particle is smaller than the thickness of formed coating layer. When the particle size is too small, a resistance at a contact point between particles increases, so that a desirable resistivity is not obtained. In view of such circumferences, an average particle size of the electroconductive particle is preferably 0.02 μm to 15 μm. When a wire having a small diameter is used, a pitch is narrowed. When a wire having a large diameter is used, the pitch is widened. Maximal efficiency is obtained by such optimization.

The bus bar 808 into which a relatively large current can flow to allow a current to flow from the grid electrode 807 into a terminal is formed by screen printing.

Next, preferred examples of the present invention will be described with reference to the accompany drawings.

### Example 1

In this example, the solar cell having the single cell structure shown in FIG. 2 was manufactured.

First, an ingot was produced using a nugget of chemical grade metallurgical grade silicon from Norway as a raw material. After 60 kg of the nugget was cleaned with acid, the nugget was placed in the apparatus shown in FIG. 17. In the crucible 1703, a bottom surface is 30 cm square and a depth is 40 cm. The heater 1702 was controlled and the entire silicon was melted for 10 hours to degas. After that, slow cooling was performed by the cooling plate 1701, so that the silicon was solidified from the bottom surface of the crucible 1703 as shown in FIG. 17. Reference numeral 1704 denotes the solidified silicon and 1705 denotes the melted silicon. The solidification was completed after 10 hours. Then, cooling was performed for 10 hours while the output of the heater 1702 was gradually reduced. Grain boundaries was extended in the longitudinal direction in the ingot produced by the solidification. A sample were taken from the ingot by slicing and the surface of the sample was etched. A hole resistance of the sample was measured. Resistivity was 0.02 Ω·cm in p-type. A part within 5 cm from the surface of the ingot and a part within 2.5 cm from the bottom surface and inner wall of the crucible were removed by a band saw. Four blocks, each of which has 125 mm square and 250 mm in length were taken such that the longitudinal direction becomes perpendicular to a crystal growth direction (direction extended from the bottom surface of the crucible 1703 to an opening portion thereof). Then, 50 bases, each of which has 125 mm square and 300 μm in thickness were taken from the block by a multi-wire saw. After solvent cleaning, each of the bases was planer-etched using a mixture of nitric acid, acetic acid, and hydrofluoric acid for 2 minutes to remove sawing remainders of the wire saw left on the base, thereby obtaining a gloss surface.

A polycrystalline silicon layer was grown on the surface of the obtained base by the liquid phase growth apparatus shown in FIG. 18. First, indium was introduced into the crucible 1803 and heated at 950° C. The temperature was maintained for melting. Next, a p-type polycrystalline silicon plate of a solar cell class having a thickness of 3 mm instead of the base was set in the carrier 1805 and immersed into the melted indium. The melt 1804 was prepared by melting the silicon into the indium to cause saturation. In order to set the conductivity type of the polycrystalline silicon layer to a p⁺-type, gallium was added to the melt. Next, the polycrystalline silicon plate was temporarily lifted up. Instead, five bases prepared in advance were set in the carrier 1805. In addition, four bases for resistivity measurement, each of which is made of n-type polycrystalline silicon were also set. An atmosphere around the crucible was replaced by hydrogen and then the melt 1804 was cooled at a rate of 1° C. per minute. When the temperature of the melt reaches 945° C., the bases were immersed into the melt. After the growth was maintained for 20 minutes, the bases 1806 were lifted from the melt and then taken from the carrier 1805. The polycrystalline silicon layer 202 having a thickness of about 5 μm was grown on the base 1806.

When the surface of the sample was examined by a laser microscope capable of performing three-dimensional measurement, minute unevenness having a pitch of 5 μm to 10 μm was observed. The unevenness was composed of terraces oriented in a specific direction for each crystal grain. With respect to the observed crystal grains, there were a crystal grain including the facet surfaces 1002 (produced by crystal growth) composing the groove-shaped unevenness as shown in FIG. 10 and a crystal grain including the facet surfaces 1102 composing the triangular pyramid or pentahedron shaped unevenness shown in FIG. 11A or 11B. The unevenness of the sample had the same shapes as in FIGS. 12 and 13. However, a size and a pitch were varied. That is, a crystal grain in one base had a substantially flat growth surface. When a shape type in the sample was divided into three types, that is, the groove-shaped unevenness, the triangular pyramid or pentahedron shaped unevenness, and the substantially flat shape, an existence ratio among the three types was 3:3:2. The uneven difference in each of the groove-shaped unevenness and the triangular pyramid or pentahedron shaped unevenness was distributed in a range of about 0.5 μm to 4 μm and an average thereof was about 2 μm. The tilt angle of the facet surface relative to the base in each of the groove-shaped unevenness and the triangular pyramid or pentahedron shaped unevenness was varied in a range of about 5° to 45° and an average thereof was 31°.

In another sample, a liquid phase growth time was changed. When the growth time is long, the polycrystalline silicon layer 202 became thicker. The uneven difference of the unevenness also increased. Therefore, it was determined that the unevenness on the surface could be controlled according to the growth condition.

Next, the resistivity of the polycrystalline silicon layer grown on the n-type base for resistivity measurement was measured by four-point probe measurement. The resistivity was 0.02 Ω·cm. Here, the n-type base was used because a depletion layer was formed between the n-type base and the p-type polycrystalline silicon layer 202 to electrically separate the grown polycrystalline silicon layer from the base, thereby measuring the resistivity with high precision. Although the polycrystalline silicon layer completely covered not only the front surface of the base but also the end surfaces thereof, the growth on the rear surface of the base did not appear.

Thus, the polycrystalline silicon substrate for solar cell was completed. The above-mentioned growth was performed ten times on all 50 bases. A sectional structure of the polycrystalline silicon layer and resistivity thereof were checked every growth, so that preferable reproduction was obtained.

Subsequently, a solar cell was manufactured using the polycrystalline silicon substrate. First, the metallic electrode layer 203 which is made of silver and has a thickness of 0.5 μm was formed on the polycrystalline silicon layer 202 using a DC sputtering apparatus which is not shown. Next, a ZnO layer with a thickness of 1 μm serving as the oxide semiconductor layer 204 was formed using a RF sputtering apparatus which is not shown. After that, the n-layer 205 was formed using a silane gas, a hydrogen gas, and phosphine as raw materials by a plasma CVD apparatus including a RF power source, which is not shown. The i-layer 206 was formed using a silane gas and a hydrogen gas as raw materials. Then, the p-layer 207 was formed using a silane gas and diborane as raw materials. Next, an ITO film was formed as the transparent electrode layer 208 by a known sputtering method.

In the solar cell having the single cell structure, which was produced by the above-mentioned process, a surface reflection spectrum was measured by a spectral reflectometer provided with an integrating sphere. As a result, the reflectance was a local minimum at a wavelength of 580 nm and 10% or less in a wavelength range of 450 nm to 1000 nm. When a silicon nitride film was deposited on a silicon wafer whose surface was polished in the same condition, the reflectance was a local minimum at a wavelength of 650 nm and a wavelength at which the reflectance was 10% or less was in a range of 550 nm to 800 nm. Thus, the reflection prevention effect of the minute unevenness composed of the facet surfaces was clearly achieved.

Next, an aluminum paste was printed for a rear electrode (not shown) using a screen printing machine and dried. After that, a pattern of a silver paste was printed as a grid electrode (not shown) on the surface of the rear electrode. The resultant substrate was placed in an infrared belt baking furnace. A baking condition was 100 mm per minute at 200° C.

Final, in order to form a solder coating layer (not shown), the substrate was set in the cassette. The substrate was immersed in a flux bath and dried by hot air. After that, the substrate was immersed in a solder flow bath for a predetermined time and the cassette was lifted up. A flux on the substrate was cleared and then the substrate was dried. Only a grid of the silver paste was coated with solder.

By the above-mentioned process, 50 solar cells were manufactured. The characteristics of the solar cells were evaluated using a solar simulator having an irradiation light spectrum of AM1.5. Short-circuit current values of the 50 solar cells were 18 mA/cm²±1.5 mA/cm², which were preferable characteristics. For comparison, a solar cell in which the surface of the polycrystalline silicon layer 202 was made substantially flat in the structure shown in FIG. 2 was manufactured based on substantially the same condition as described above except for a different liquid phase growth condition. Spectral sensitivity of the prototype of the solar cell and spectral sensitivity of the solar cell for comparison were measured. As a result, quantum efficiency was relatively improved by 8% at a wavelength of 400 nm and by 10% at a wavelength of 700 nm. The improvement of the quantum efficiency may be expected from a reduction in reflection on the light incident side and an increase in spectral sensitivity due to the scattering on the rear surface.

### Example 2

In this example, the solar cell having the double cell structure shown in FIG. 3 was manufactured.

First, as in example 1, the polycrystalline silicon of the base 301 was formed and then the polycrystalline silicon layer 302 was formed thereon by performing liquid phase growth for 1 hour. The thickness of the polycrystalline silicon layer 302 was about 30 μm. According to observations using a laser microscope, minute unevenness was formed on the surface of the polycrystalline silicon layer 302. When a shape type was divided into the groove-shaped unevenness, the triangular pyramid or pentahedron shaped unevenness, and the substantially flat shape, an existence ratio among those types was 4:3:1. The uneven difference of the unevenness was 0 μm to 15 μm which is a half of a maximal thickness of 30 μm of the polycrystalline silicon layer 302 and an average thereof was about 7 μm. The tilt angle of the facet surface relative to the base was varied in a range of about 0° to 45° and an average thereof was 30°.

Next, in order to form the emitter layer 303, an application solution containing boron was applied by a spinner. After the application solution was dried, 50 substrates were arranged with a state in which the rear surfaces of every two substrates face to each other and placed in a horizontal type thermal treatment furnace. Phosphorus was thermally diffused at 900° C. in a nitrogen atmosphere and then a film of the application solution was removed by etching. In this process, thermal diffusion was performed on the substrate. Thus, a pn-junction was produced from the polycrystalline silicon layer 302 and the emitter layer 303 to prepare the bottom cell.

Next, as in Example 1, the n-layer 304, the i-layer 305, and the p-layer 306 were made of amorphous silicon to form the top cell. In this case, when a current value obtained from the top cell and a current value obtained from the top cell were made equal to each other, the characteristic of the solar cell became maximum. Therefore, it is necessary to set the thickness of the i-layer 305 of the top cell to a suitable thickness. In this example, the thickness of the i-layer 305 was set to 0.3 μm, with the result that the current value from the top cell and the current value from the top cell became equal to each other.

Next, as in Example 1, the transparent electrode layer 307 was formed and then a grid electrode (not shown) and a rear electrode (not shown) were formed.

By the above-mentioned process, 50 solar cells were manufactured. As in Example 1, the characteristics of the solar cells were evaluated using a solar simulator having an irradiation light spectrum of AM1.5. Short-circuit current values of the 50 solar cells were 15 mA/cm²±1.2 mA/cm², which were preferable characteristics. For comparison, a solar cell in which the surface of the polycrystalline silicon layer 302 was made substantially flat in the structure shown in FIG. 3 was manufactured based on substantially the same condition as described above except for a different liquid phase growth condition. Spectral sensitivity of the prototype of the solar cell and spectral sensitivity of the solar cell for comparison were measured. As a result, quantum efficiency was relatively improved by 8% at a wavelength of 400 nm. The improvement of the quantum efficiency may be expected from a reduction in reflection on the light incident side.

As described above, according to the preferred examples of the present invention, it is possible to provide a structure of a photovoltaic device that prevents a reduction in photoelectric conversion efficiency due to the absence of preferable unevenness, an increase in cost due to the use of an expensive material, and a reduction in throughput in the conventional photovoltaic device, includes a power generating layer made from a thin film, which is formed in advance on a low cost substrate having preferable unevenness, and has a preferable characteristic and high productivity, and a method of manufacturing the photovoltaic device having the structure.

This application claims priority from Japanese Patent Application No. 2003-375546 filed Nov. 5, 2003, which is hereby incorporated by reference herein.

1. A photovoltaic device comprising:
a substrate; and
a thin film semiconductor in which at least one pin junction is formed, on the substrate,
wherein the substrate comprises:
a base of polycrystalline silicon; and
a polycrystalline silicon layer formed on the base by liquid phase growth, and
wherein at least a part of a surface of the polycrystalline silicon layer has unevenness composed of facet surfaces.

2. The photovoltaic device according to claim 1, wherein the base is a slice of a polycrystalline silicon ingot produced by melting and solidifying silicon.

3. The photovoltaic device according to claim 1, wherein at least a part of the unevenness on the surface of the polycrystalline silicon layer has a groove shape.

4. The photovoltaic device according to claim 1, wherein at least a part of the unevenness on the surface of the polycrystalline silicon layer has a triangular pyramid shape or a pentahedron shape.

5. The photovoltaic device according to claim 1, wherein an average of tilt angles of the facet surfaces forming the unevenness is equal to or larger than 30° relative to the base.

6. The photovoltaic device according to claim 1, wherein an average of uneven differences of the unevenness is 0.05 μm to 10 μm.

7. The photovoltaic device according to claim 1, wherein a metallic electrode layer is further formed on the surface of the polycrystalline silicon layer.

8. The photovoltaic device according to claim 7, wherein an oxide semiconductor layer is further formed on the surface of the metallic electrode layer.

9. The photovoltaic device according to claim 1, wherein the polycrystalline silicon layer comprises high purity silicon and a layer having a conductivity type different from a conductivity type of the polycrystalline silicon layer comprising high purity silicon is formed on the polycrystalline silicon layer comprising the high purity silicon to form a pn-junction for serving as a bottom cell of the photovoltaic device.

10. The photovoltaic device according to claim 9, wherein an oxide semiconductor layer is further formed on the surface of the polycrystalline silicon layer comprising the high purity silicon.

11. The photovoltaic device according to claim 9, wherein the conductivity type of the polycrystalline silicon layer comprising the high purity silicon is equal to a conductivity type of the polycrystalline silicon of the base and resistivity of the polycrystalline silicon layer comprising the high purity silicon is 0.1 Ω·cm to 10 Ω·cm.

12-15. (canceled)
